(19) United States
(12) Patent Application Publication
(10) Pub. No.: US 2013/0214817 A1
(43) Pub. Date: Aug. 22, 2013

(54) COMMAND DETECTING DEVICE

(71) Applicants: Kenji Sugiura, Osaka (JP); Yasushi Kato, Kyoto (JP)

(72) Inventors: Kenji Sugiura, Osaka (JP); Yasushi Kato, Kyoto (JP)

(73) Assignee: PANASONIC CORPORATION, Kadoma-shi, Osaka (JP)

(21) Appl. No.: 13/883,514

(22) PCT Filed: Jul. 30, 2012
(86) PCT No.: PCT/JP2012/004823

§ 371 Date: May 3, 2013

(30) Foreign Application Priority Data
Aug. 3, 2011 (JP) 2011-169842

(51) Int. Cl. H03K 5/22

(52) U.S. Cl. CPC H03K 5/22
USPC 327/77

(57) ABSTRACT

A command detecting device of the present invention includes a comparator, a detection state selector, a time detector, and a detection time switch. The comparator compares a command input from the outside with a certain voltage value and outputs its comparison result as a first state or a second output state. The detection state selector selects an output state that has been determined as a valid output state out of the two output states from the comparator. The time detector measures a duration time of the valid output state and switches the control command when the duration time reaches a given set time. The detection time switch switches the set time for the time detector. The output state selected as the valid output state by the detection state selector is switched by the control command.

### TECHNICAL FIELD

The present invention relates to a command detecting device for driving a brushless DC motor, for example, used in air-conditioning equipment, a water heater including a fan motor for combustion, an air cleaner, and information-processing equipment such as a copier and a printer.

### BACKGROUND ART

Conventionally, to provide a control command to a brushless DC motor (hereinafter, simply described as motor), the control command is determined by converting the value of applied analog voltage into velocity or torque in some cases. Alternatively, a control command for switching the control state is determined by a result of comparing the analog voltage value with a certain voltage value in other cases. In case of comparing the analog voltage value with the certain voltage value, a comparator having hysteresis is used as a comparator for voltage values so that a control command is not be changed in response to unintended minute fluctuations in the voltage value.

FIG. 3 is a block diagram of a conventional command detecting device. In FIG. 3, comparator 120 having hysteresis included in command detecting device 110 compares a command input applied from the outside with a certain voltage value movable for hysteretic operation and outputs a control command.

FIG. 4 illustrates operation of the conventional command detecting device. Operation of conventional command detecting device 110 is described using FIG. 4. When a command input (voltage value) applied from the outside exceeds threshold A, the control command is switched from control state 1 to control state 2, and the threshold is switched from threshold A to threshold B for hysteretic operation. After that, this allows the control command to maintain control state 2 even if the command input falls below threshold A as long as the command input exceeds threshold B. Next, when the command input falls below threshold B, the control command switches from control state 2 to control state 1. Setting the voltage difference between threshold A and threshold B higher than unintended minute fluctuations in the voltage value of the command input, for example, prevents an unintended change of the control command.

The conventional technology described in patent literature 1 moderates the voltage change of a command input with resistors and capacitors. This allows a comparator to operate so as to avoid an effects caused by chattering during a time period in which chattering is generated when the switch is changed, thereby preventing an unintended change of the control command.

The circuit to which a command input is applied is typically provided with an input range. It is required for the input range to be effectively used to receive various commands for control. However, in command detecting device 110 in the above conventional technology, a wider voltage width is required for detecting a command input.

As shown in FIG. 4, thresholds A and B respectively include electrical variations α and β. For hysteretic operation to avoid an unintended change of the control command due to minute fluctuation in the command input, a voltage difference is required between thresholds A and B. Hence, a voltage range of at least (A−B+α+β) is required to detect this command input. This narrows an input range that can be used for a command input for other controls or makes a command detecting device unusable.

The conventional method using resistors and capacitors may cause fluctuation in the control command due to minute fluctuations in the command input except for the command input with its fluctuation time roughly determined such as fluctuation time caused by chattering generated when the switch is changed.

PTL 1 Japanese Patent Unexamined Publication No. S60-239116

### SUMMARY OF THE INVENTION

A command detecting device of the present invention includes a comparator, a detection state selector, a time detector, and a detection time switch. The comparator compares a command input from the outside with a certain voltage value and outputs its comparison result as a first or second output state. The detection state selector selects an output state that has been determined as valid output out of the two output states from the comparator. The time detector measures a duration time of the valid output state and switches the control command when the duration time reaches a given set time. The detection time switch switches the set time for the time detector. The output state selected as a valid output state by the detection state selector is switched by the control command.

As a result, the present invention reduces a voltage width required for command detection without moving the threshold for hysteretic operation of the comparator, while suppressing fluctuations in the control command due to unintended, minute fluctuations in the command input.

### BRIEF DESCRIPTION OF THE DRAWINGS

FIG. 1 is a block diagram of a command detecting device according to an embodiment of the present invention.

FIG. 2 illustrates operation of the command detecting device according to the embodiment of the present invention.

FIG. 3 is a block diagram of a conventional command detecting device.

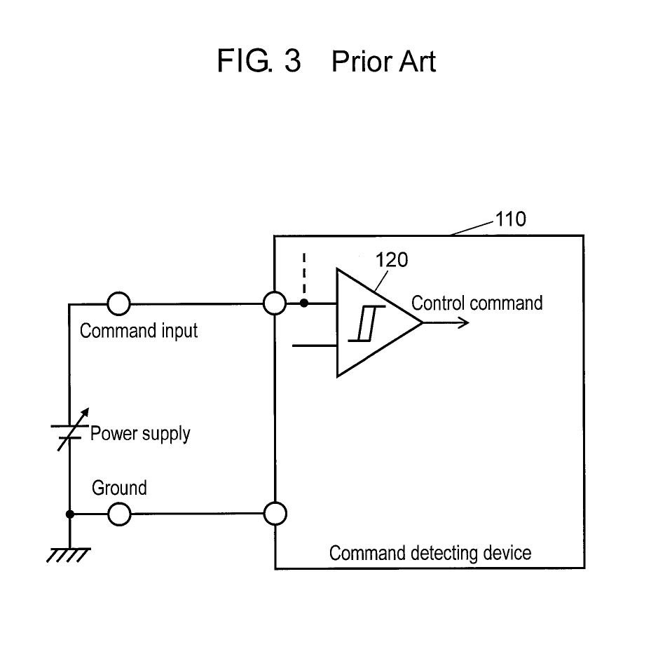

FIG. 4 illustrates operation of the conventional command detecting device.

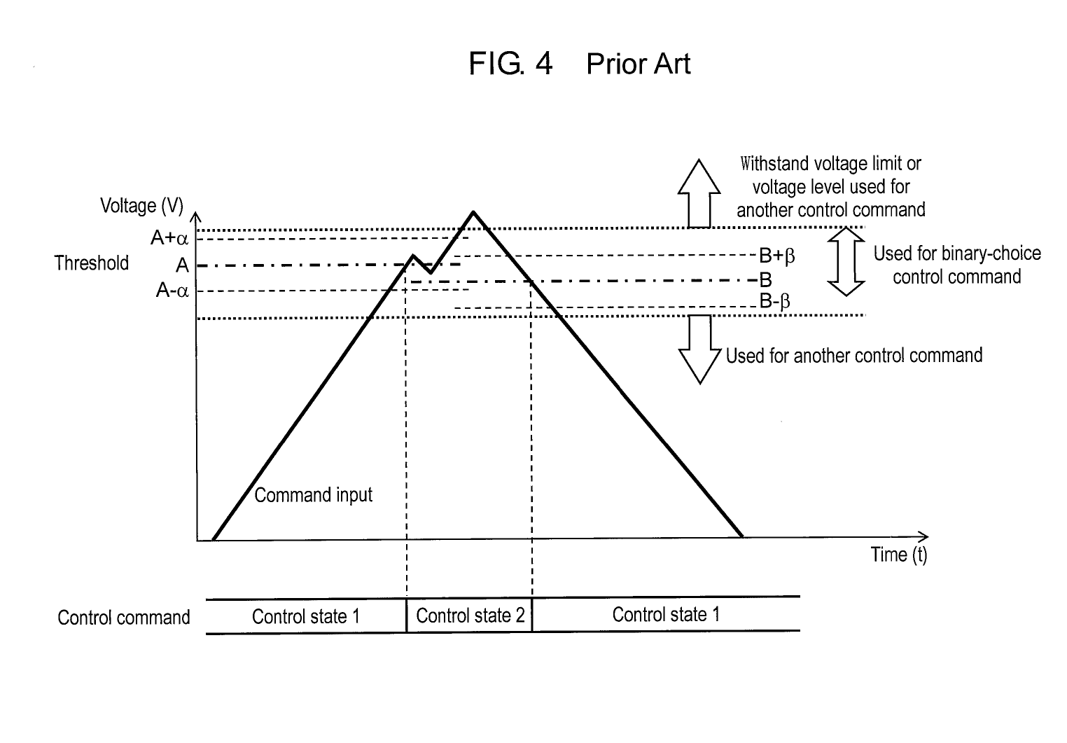

### DETAILED DESCRIPTION OF THE PREFERRED EMBODIMENT

Hereinafter, a detailed description of the present invention will be given below with reference to the following preferred embodiment thereof, which does not limit the scope of the invention.

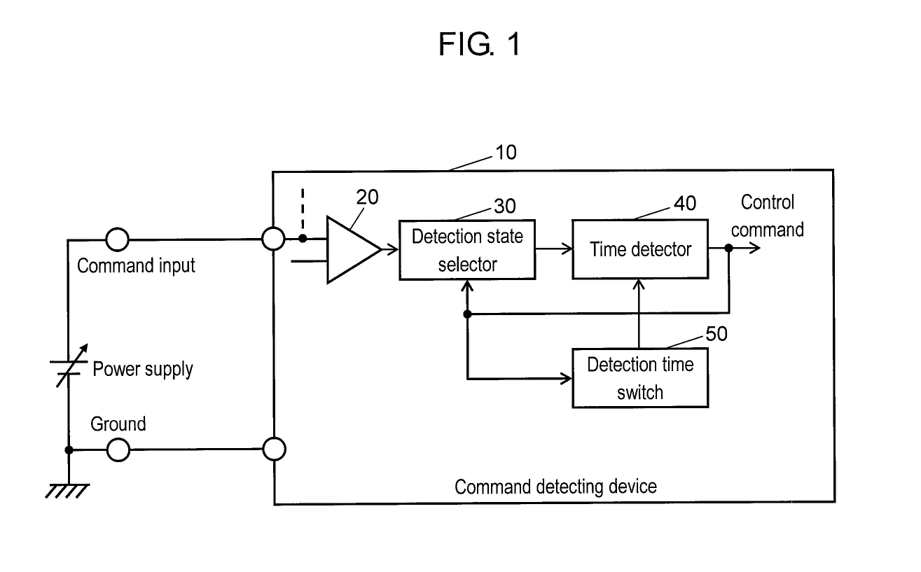

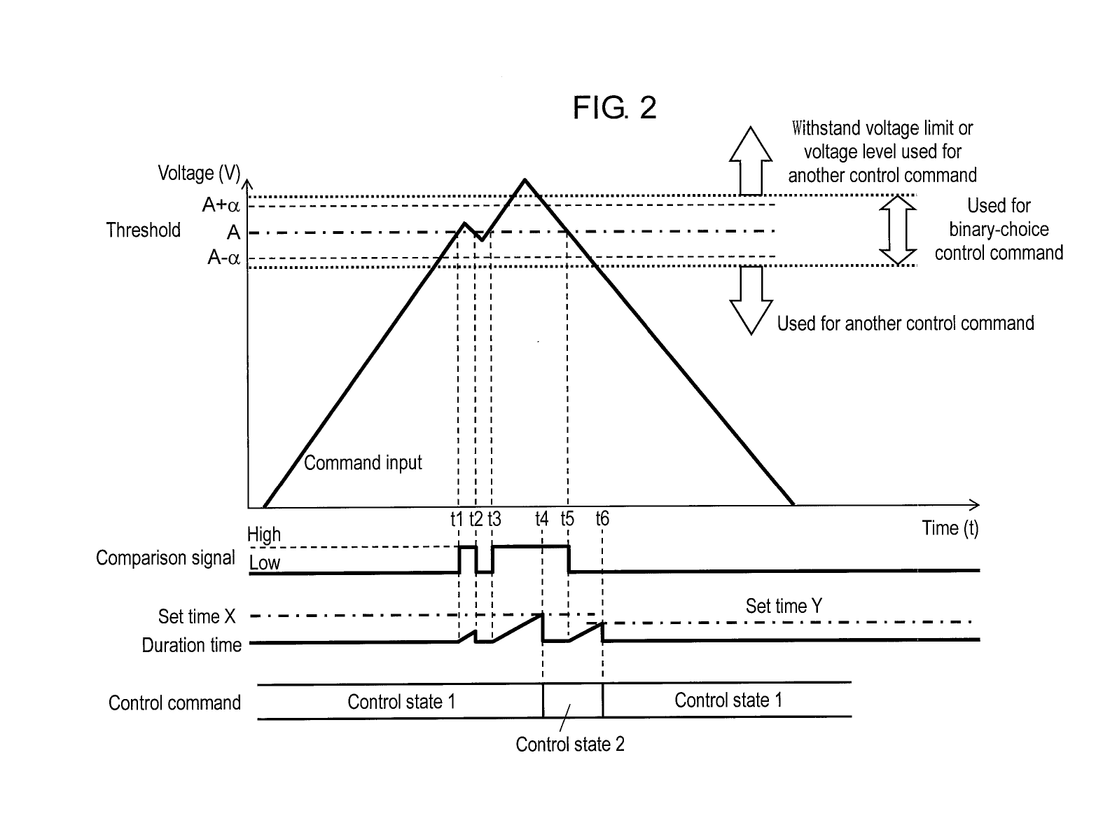

FIG. 1 is a block diagram of a command detecting device according to an embodiment of the present invention. FIG. 2 illustrates operation of the command detecting device.

As shown in FIG. 1, command detecting device 10 according to the embodiment includes comparator 20, detection state selector 30, time detector 40, and detection time switch 50. In FIG. 1, a command input applied from the outside is input to comparator 20 included in command detecting device 10. Comparator 20 compares the command input (voltage value) with a certain voltage value and outputs its comparison result as signal High (first output state) or signal Low (second output state). Detection state selector 30 selects a signal (output state) that has been determined as a valid output state out of signal High or signal Low (two output state) output from comparator 20. Time detector 40 measures a duration time of the valid signal and outputs a control command according to the valid signal when the duration time reaches a given set time. A signal determined as a valid signal by detection state selector 30 is switched by the control command output from time detector 40. The above set time for time detector 40 is determined by a setting signal output from detection time switch 50, where the setting signal may be switched using the control command. In other words, the above set time for time detector 40 may be switched by the control command output from time detector 40.

Operation of command detecting device 10 is explained using FIG. 2. FIG. 2 illustrates the respective time changes of a command input, comparison signal, duration time, and control command. Here, the duration time refers to a time period during which a valid signal out of the comparison signals continues. When a command input applied from the outside exceeds threshold A, the comparison signal, which is an output signal from comparator 20, changes from Low to High (time t1). At this moment, if the signal determined as a valid signal by detection state selector 30 is High, time detector 40 starts measuring the duration time. In FIG. 2, the horizontal axis indicates an elapsed time and indicates the duration time the vertical direction. Accordingly the duration time rises in accordance with the elapsed time. If the command input falls below threshold A before the duration time reaches given set time X (time t2), comparator 20 outputs signal Low. In this case, detection state selector 30 determines the comparison signal as invalid, and thus the duration time measured by time detector 40 is reset. This keeps the control command output from time detector 40 unchanged, thereby maintaining control state 1.

When the command input exceeds threshold A again (time t3), time detector 40 starts measuring a duration time. When the measured duration time reaches set time X determined by detection time switch 50, the control command changes to switch the control state from state 1 to state 2 (time t4). At this moment, the signal determined as a valid signal by detection state selector 30 changes from High to Low responsive to a change of the control command, and detection state selector 30 determines the comparison signal as an invalid signal to reset the duration time. Next, when the command input falls below threshold A (time t5), time detector 40 starts measuring a duration time. When the measured duration time reaches set time Y determined by detection time switch 50, the control command for time detector 40 changes to switch the control state from state 2 to state 1.

Here, the set time determined by detection time switch 50 allows easiness of switching the control command to vary by switching the set time using the control command, where the set time does not necessarily need to be switched. The given set time determined by detection time switch 50 may be switched by any way other than by the control command.

This operation suppresses a voltage width required for command detection better than a conventional command detecting device, without hysteretic operation provided for the threshold of the comparator, while suppressing fluctuations in the control command due to unintended minute fluctuations in the command input.

As described hereinbefore, a command detecting device of the present invention includes a comparator, a detection state selector, a time detector, and a detection time switch. The comparator compares a command input from the outside with a certain voltage value and outputs its comparison result as a first or second output state. The detection state selector selects an output state that has been determined as a valid output state out of the two output states from the comparator. The time detector measures a duration time of the valid output state and switches the control command when the duration time reaches a given set time. The detection time switch switches the set time for the time detector. The output state determined as the valid state selected by the detection state selector is switched by the control command.

This operation suppresses a voltage width required for command detection without moving the threshold for hysteretic operation of the comparator, while suppressing fluctuations in the control command due to unintended minute fluctuations in the command input.

In a command detecting device of the present invention, the set time switched by the detection time switch may be switched by the control command. This allows easiness of switching the control command to vary.

INDUSTRIAL APPLICABILITY

A command detecting device of the present invention is extensively used for applications that need to suppress fluctuation in a control command due to unintended minute fluctuations in a drive device for a motor and so on.

REFERENCE MARKS IN THE DRAWINGS

10 Command detecting device

20 Comparator

30 Detection state selector

40 Time detector

50 Detection time switch

1. A command detecting device comprising:
a comparator operable to make comparison between a command input from an outside and an certain voltage and output a result of the comparison as a first output state or a second output state;
a detection state selector operable to select an output state determined as a valid output state out of the first and second output states from the comparator;
a time detector operable to measure a duration time of the valid output state and switch the control command when the duration time reaches a given set time; and
a detection time switch operable to switch the given set time in the time detector,
wherein the valid output state selected by the detection state selector is switched by the control command.

2. The command detecting device of claim 1, wherein the given set time switched by the detection time switch is switched by the control command.
